(19) United States
(12) Patent Application Publication
(10) Pub. No.: US 2025/0349463 A1
(43) Pub. Date: Nov. 13, 2025

(54) EMBEDDING METHOD AND EMBEDDED STRUCTURE FOR MAGNETIC TRANSFORMER, ELECTRONIC DEVICE AND STORAGE MEDIUM

(71) Applicant: Zhuhai YUEXIN Semiconductor Limited Liability Company, Zhuhai (CN)

(72) Inventors: Xianming CHEN, Zhuhai (CN); Lei FENG, Zhuhai (CN); Xiaowei XU, Zhuhai (CN); Benxia HUANG, Zhuhai (CN); Yejie HONG, Zhuhai (CN)

(73) Assignee: Zhuhai YUEXIN Semiconductor Limited Liability Company, Zhuhai (CN)

(21) Appl. No.: 18/927,841

(22) Filed: Oct. 25, 2024

(30) Foreign Application Priority Data
May 11, 2024 (CN) 202410581416.0

(51) Int. Cl. H01F 38/14; H01F 27/06; H01F 27/28; H01F 27/32; H01F 41/02; H01F 41/04; H01F 41/26

(52) U.S. Cl. CPC H01F 38/14; H01F 27/06; H01F 27/2804; H01F 27/32; H01F 41/0266; H01F 41/04; H01F 41/26

(57) ABSTRACT

An embedding method and embedded structure for a magnetic transformer, an electronic device and a storage medium are disclosed. The method includes: providing a copper-clad substrate; electroplating on surfaces of the copper-clad substrate to form a coil; laminating prepregs and copper sheets to form a first substrate; drilling the first substrate to define a first and second through hole; filling a magnetic material in the first through holes to form first embedded magnets; forming a metal layer on an inner wall of the second through hole and surfaces of the first substrate; manufacturing conductive pillars and sacrificial blocks; laminating insulating layers; etching the sacrificial block to define cavities; filling a magnetic material in the cavities to form second embedded magnets; and manufacturing a circuit and a solder resist layer on surfaces of the insulating layer to form a package substrate.

### CROSS-REFERENCE TO RELATED APPLICATION

This application is based on and claims the benefit of priority from Chinese Patent Application No. 2024105814160, filed on May 11, 2024, the entirety of which is incorporated by reference herein.

### TECHNICAL FIELD

The present disclosure relates to the technical field of package structures, and particularly to an embedding method and embedded structure for a magnetic transformer, an electronic device and a storage medium.

### BACKGROUND

With the continuous development of electronic technology, an integration degree of consumer electronic products such as a computer and a telecommunication device are getting higher and higher. With the rapid development of a packaging method for an embedded chip by using a supporting frame and the application thereof in practical production, the demands for miniaturization, thinness and high integration of electronic devices in the market has been met.

A transformer in existing isolated power supply module or device has a large size, because numbers of turns of primary and secondary inductor coils of the transformer are large. At present, the transformer is usually fixed to a package substrate by surface mounting, and a manufacturing technology of this scheme is mature. However, due to the need for secondary surface mounting, not only a production process is added and a production cost is increased, but also a volume of a packaged product is large, which cannot meet the market demands for miniaturization, high integration and high performance. In addition, due to the large size of the transformer, the transformer cannot be effectively embedded inside the package substrate by an existing embedding technology.

### SUMMARY

The present disclosure aims to solve at least one of the technical problems in the existing technology. Therefore, the present disclosure provides an embedding method and embedded structure for a magnetic transformer, an electronic device and a storage medium, which can effectively embed the transformer inside a package substrate to reduce a size of the package substrate.

In one aspect, an embedding method for a magnetic transformer according to an embodiment of the present disclosure includes the following steps of:
providing a copper-clad substrate;
electroplating on an upper surface and a lower surface of the copper-clad substrate to form a coil for the magnetic transformer;
laminating a prepreg and a copper sheet on both the upper surface and the lower surface of the copper-clad substrate to form a first substrate for the package substrate;
drilling the first substrate to define a plurality of first through holes penetrating through the first substrate, where at least one of the plurality of first through holes is defined inside the coil, and the rest of the plurality of first through holes is defined outside the coil;
filling a magnetic material in each of the plurality of first through holes to form a respective one of a plurality of first embedded magnets;
drilling the first substrate to define a second through hole penetrating through the first substrate, and forming a plurality of metal layers arranged respectively on an inner wall of the second through hole and an upper surface and a lower surface of the first substrate;
manufacturing a respective one of a plurality of conductive pillars and a respective one of a plurality of sacrificial blocks for each of the plurality of metal layers corresponding to the upper surface and the lower surface of the first substrate, and etching redundant part of the metal layers;
laminating, for the upper surface and the lower surface of the first substrate, an insulating layer, such that the insulating layer is flush with surfaces of the conductive pillars and the sacrificial blocks;
etching each of the plurality of sacrificial blocks to define a respective one of a plurality of cavities corresponding to the upper surface and the lower surface of the first substrate;
filling a magnetic material in each of the plurality of cavities to form a respective one of a plurality of second embedded magnets; where the plurality of first embedded magnets are coupled to the plurality of second embedded magnets to form a closed magnetic circuit, and the closed magnetic circuit and the coil form the magnetic transformer; and
manufacturing a circuit and a solder resist layer on a surface of the insulating layers to form the package substrate.

In some embodiments of the present disclosure, the step of electroplating on the upper surface and the lower surface of the copper-clad substrate to form the coil for the magnetic transformer, includes:
performing the following steps for the upper surface and the lower surface of the copper-clad substrate, including:
laminating a photosensitive emulsion film;
exposing and developing the photosensitive emulsion film to define a plurality of coil openings required;
electroplating in each of the plurality of coil opening to form a respective one of a plurality of metal wires; where the plurality of metal wires collectively form the coil for the magnetic transformer; and
removing the photosensitive emulsion film, and etching an exposed copper foil.

In some embodiments of the present disclosure, the step of filling the magnetic material in each of the plurality of first through holes to form a respective one of the plurality of first embedded magnets, includes:
attaching a bonding adhesive film to a bottom of the first substrate;
filling the magnetic material in each of the plurality of first through holes by screen printing; and
removing the bonding adhesive film, and grinding the magnetic material to form the plurality of first embedded magnets each flush with the upper surface and the lower surface of the first substrate.

In some embodiments of the present disclosure, the step of manufacturing a respective one of a plurality of conductive pillars and a respective one of a plurality of sacrificial blocks for each of the plurality of metal layers corresponding to the upper surface and the lower surface of the first substrate, and etching redundant part of the metal layers, includes:
performing the following steps for the metal layer on the upper surface and the lower surface of the first substrate, including:
laminating a photosensitive film on the surface of the metal layer;
windowing the photosensitive film to form a conductive pillar window and a sacrificial block window;
electroplating in the conductive pillar window to form the conductive pillar, and electroplating in the sacrificial block window to form the sacrificial block; and
removing the photosensitive film, and etching the redundant part of the metal layer.

In some embodiments of the present disclosure, the step of etching each of the plurality of sacrificial blocks to define a respective one of a plurality of cavities corresponding to the upper surface and the lower surface of the first substrate, includes:
performing the following steps for the upper surface and the lower surface of the first substrate, including:
manufacturing an etching resistant layer on the surface of the insulating layer;
windowing the etching resistant layer to expose the sacrificial block;
etching the sacrificial block to define the cavity; and
removing the etching resistant layer.

In some embodiments of the present disclosure, the step of manufacturing the circuit and the solder resist layer on the surface of the insulating layers, to form the package substrate, includes:
performing the following steps for the upper surface and the lower surface of the first substrate, including:
manufacturing the circuit on the surface of the insulating layer; where the circuit is coupled to the conductive pillar and the second embedded magnet;
manufacturing the solder resist layer on the surface of the insulating layer, and windowing the solder resist layer to form a window, so as to expose the circuit; and
carrying out a surface treatment on the circuit according to the window.

In some embodiments of the present disclosure,
the step of forming a plurality of metal layers arranged respectively on an inner wall of the second through hole and an upper surface and a lower surface of the first substrate, includes:
forming the metal layer on the inner wall of the second through hole and the upper surface and the lower surface of the first substrate by an electroless copper plating technology.

In another aspect, an embedded structure for a magnetic transformer according to an embodiment of the present disclosure is provided, which is prepared by the embedding method for the magnetic transformer in the above method embodiment according to the present disclosure.

In another aspect, an electronic device according to an embodiment of the present disclosure is provided, which includes:
a memory configured for storing a program instruction; and
a processor configured for calling the program instruction stored in the memory which,
when executed by the processor, causes the processor to carry out the embedding method for the magnetic transformer in the above method embodiment according to the present disclosure.

In yet another aspect, a storage medium according to an embodiment of the present disclosure is provided, where the storage medium stores a computer-executable instruction, which, when executed by a computer, causes the computer to execute the embedding method for the magnetic transformer in the above method embodiment according to the present disclosure.

The embedding method and embedded structure for the magnetic transformer, the electronic device and the storage medium according to the embodiments of the present disclosure have at least the following beneficial effects: the coil of the transformer is embedded in the package substrate, and the magnetic material is introduced around the coil to form the closed magnetic circuit, which can greatly increase an inductance value of an inductor, effectively reduce an input voltage frequency, reduce a number of turns, reduce direct-current resistance of the coil and an energy loss caused by the transformer, and reduce a size of the transformer at the same time, so that the isolated power supply module or device is miniaturized, the quality requirements of inductor board-level packaging are met, the cost is reduced, and the efficiency is improved.

Additional aspects and advantages of the present disclosure will be given in part in the following description, which will become apparent from the following description or may be understood through practice of the present disclosure.

### BRIEF DESCRIPTION OF THE DRAWINGS

The above and/or additional aspects and advantages of the present disclosure will become apparent and easy to understand from the descriptions of embodiments with reference to the following drawings, wherein:

FIG. 1 is a flow chart of an embedding method for a magnetic transformer according to an embodiment of the present disclosure;

FIG. 2 is a schematic structural diagram of a copper-clad substrate according to an embodiment of the present disclosure;

FIG. 3 is a schematic structural diagram of the copper-clad substrate provided with a photosensitive emulsion film according to an embodiment of the present disclosure;

FIG. 4 is a schematic diagram of the structure formed with a coil opening according to an embodiment of the present disclosure;

FIG. 5 is a schematic diagram of the structure with a coil formed by electroplating;

FIG. 6 is a schematic diagram the structure after removing the photosensitive emulsion film and etching an exposed copper foil on a surface of the copper-clad substrate;

FIG. 7 is a top view of the coil;

FIG. 8 is a schematic structural diagram of a first substrate according to an embodiment of the present disclosure;

FIG. 9 is a schematic structural diagram of the first substrate defining a first through hole after being drilled;

FIG. 10 is a top view of the structure showing the coil and the first through hole;

FIG. 11 is a schematic diagram of the structure in which the first through hole is filled with a magnetic material;

FIG. 12 is a schematic diagram showing the structure after grinding the magnetic material to form a first embedded magnet flush with the surface of the first substrate;

FIG. 13 is a top view of the structure showing the coil and the first embedded magnet;

FIG. 14 is a schematic structural diagram showing the structure after drilling the first substrate to define a second through hole;

FIG. 15 is a schematic structural diagram showing the structure after forming a metal layer on an inner wall of the second through hole and the surface of the first substrate;

FIG. 16 is a schematic structural diagram showing the structure after laminating a photosensitive film on a surface of the metal layer, and windowing the photosensitive film to form a conductive pillar window and a sacrificial block window;

FIG. 17 is a schematic structural diagram showing the structure after manufacturing a conductive pillar and a sacrificial block on the surface of the metal layer;

FIG. 18 is a schematic structural diagram showing the structure after laminating the insulating layer on the surface of the first substrate;

FIG. 19 is a schematic structural diagram showing the structure after etching the sacrificial block to define a cavity;

FIG. 20 is a schematic structural diagram showing the structure after filling a magnetic material in the cavity to form a second embedded magnet;

FIG. 21 is a top view of a closed magnetic circuit and the coil;

FIG. 22 is a schematic structural diagram of a package substrate according to an embodiment of the present disclosure;

FIG. 23 is a schematic structural diagram of a large-board-level magnetic transformer embedded product; and

FIG. 24 is a schematic structural diagram of an embedded structure for a single magnetic transformer of the large-board-level magnetic transformer embedded product.

### REFERENCE NUMERALS

100 refers to copper-clad substrate, 110 refers to photosensitive emulsion film, 120 refers to coil opening, 200 refers to coil, 300 refers to prepreg, 400 refers to copper sheet, 500 refers to first substrate, 510 refers to first through hole, 520 refers to second through hole, 530 refers to metal layer, 540 refers to bonding adhesive film, 550 refers to photosensitive film, 560 refers to conductive pillar window, 570 refers to sacrificial block window, 600 refers to first embedded magnet, 700 refers to conductive pillar, 800 refers to sacrificial block, 810 refers to cavity, 900 refers to insulating layer, 1000 refers to second embedded magnet, 1100 refers to circuit, 1200 refers to solder resist layer, and 1300 refers to package substrate.

### DETAILED DESCRIPTION

Embodiments of the present disclosure are described in detail hereinafter, examples of the embodiments are shown in the drawings, and the same or similar reference numerals throughout the description denote the same or similar elements or elements having the same or similar functions. The embodiments described hereinafter with reference to the drawings are illustrative and are only used to explain the present application, but cannot be understood as limiting the present application. The numbers of the steps in the following embodiments are only set for convenience of explanation, and the sequence of the steps is not restricted. The execution sequence of the steps in the embodiments may be adjusted adaptively according to the understanding of those skilled in the art.

In the description of the present disclosure, it should be understood that, the orientation or position relationship related to the orientation description, such as the orientation or position relationship indicated by the terms “upper”, “lower”, “front”, “rear”, “left”, “right”, and the like is based on the orientation or position relationship shown in the drawings, which is only used for convenience of the description of the present disclosure and simplification of the description instead of indicating or implying that the indicated device or element must have a specific orientation, and be constructed and operated in a specific orientation, and thus should not be understood as a limitation to the present disclosure.

The terms “first”, “second”, “third”, “fourth”, etc. in the specification, the claims and the drawings of the present disclosure are used to distinguish different objects, and are not used to describe a specific order. In addition, the terms “including” and “having” and any variations thereof are intended to cover non-exclusive inclusion. For example, a process, method, system, product or device including a series of steps or units is not limited to those steps or units listed, but optionally further includes other steps or units not clearly listed, or optionally further includes other steps or units inherent to the process, method, product or device.

The “embodiment” mentioned in the present disclosure means that the specific features, structures or performances described with reference to the embodiment may be included in at least one embodiment of the present disclosure. The appearance of this phrase in various places in the specification does not necessarily refer to the same embodiment, nor is it an independent or alternative embodiment mutually exclusive with other embodiments. It is understood explicitly and implicitly by those skilled in the art that the embodiments described herein may be combined with other embodiments.

With the continuous development of electronic technology, an integration degree of consumer electronic products such as a computer and a telecommunication device is getting higher and higher. With the rapid development of a packaging method for an embedded chip by using a supporting frame and the application thereof in practical production, the demands for miniaturization, thinness and high integration of electronic devices in the market has been met.

A transformer in existing isolated power supply module or device has a large size, because numbers of turns of primary and secondary inductor coils of the transformer are large. At present, the transformer is usually fixed to a package substrate by surface mounting, and a manufacturing technology of this scheme is mature. However, due to the necessary for secondary surface mounting, not only a production process is added and a production cost is increased, but also a volume of a packaged product is large, which cannot meet the market demands for miniaturization, high integration and high performance. In addition, due to the large size of the transformer, the transformer cannot be effectively embedded inside the package substrate by an existing embedding technology.

Therefore, an embodiment of the present disclosure provides an embedding method and embedded structure for a magnetic transformer, an electronic device and a storage medium. A coil of the transformer is embedded in a package substrate, and a magnetic material is added around the coil to form a closed magnetic circuit, which can greatly increase an inductance value of an inductor, effectively reduce an input voltage frequency, reduce a number of turns, reduce direct-current resistance of the coil and an energy loss caused by the transformer, and reduce a size of the transformer at the same time, so that an isolated power supply module or device is miniaturized, the quality requirements of inductor board-level packaging are met, the cost is reduced, and the efficiency is improved.

The embedding method and embedded structure for the magnetic transformer, the electronic device and the storage medium according to embodiments of the present disclosure are described in detail hereinafter with reference to the drawings.

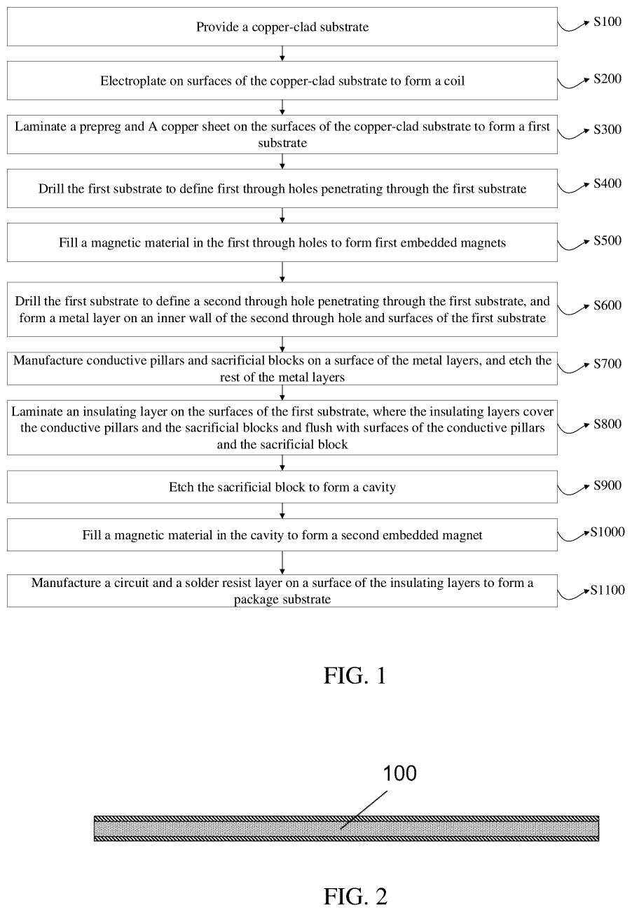

In an aspect, as shown in FIG. 1, an embedding method for a magnetic transformer according to an embodiment of the present disclosure includes the following steps.

In step S100, a copper-clad substrate 100 is provided.

As shown in FIG. 2, in this example, the copper-clad substrate 100 with copper claddings on double sides is adopted as a carrier of a package structure.

In step S200, electroplating is carried out on surfaces of the copper-clad substrate 100 to form a coil 200.

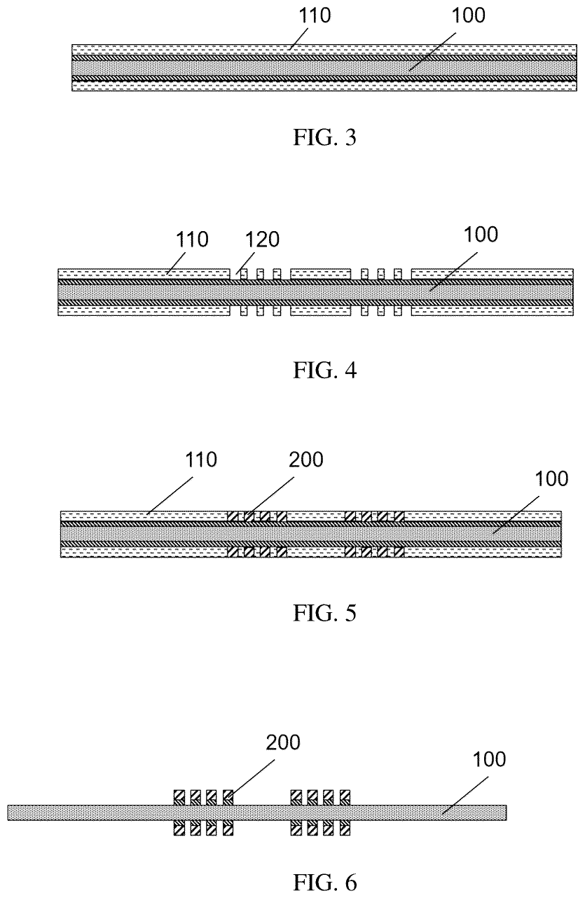

Specifically, as shown in FIG. 3 to FIG. 7, in this example, in order to form the coil 200 on the surfaces of the copper-clad substrate 100 by electroplating, the above step S200 includes the following four sub-steps of:
1. laminating a photosensitive emulsion film 110 on the surfaces of the copper-clad substrate 100;
2. exposing and developing the photosensitive emulsion films 110 to form a plurality of required coil openings 120;
3. electroplating in the coil openings 120 to form metal wires; where a plurality of metal wires collectively form the coil 200; and
4. removing the photosensitive emulsion films 110, and etching an exposed copper foil on the surfaces of the copper-clad substrate 100.

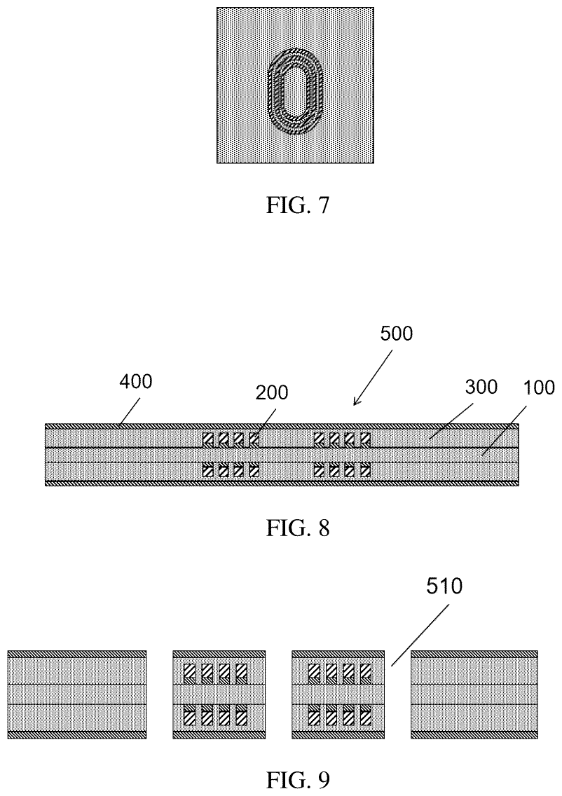

As shown in FIG. 3, the photosensitive emulsion film 110 is laminated on an upper surface and a lower surface of the copper-clad substrate 100 first; then, as shown in FIG. 4, the plurality of required coil openings 120 are defined in the photosensitive emulsion films 110 by exposure and development; as shown in FIG. 5, the metal wires are formed in the coil openings 120 by electroplating; and finally, as shown in FIG. 6, the photosensitive emulsion films 110 are removed, the surfaces of the copper-clad substrate 100 are etched to remove the redundant part of the copper foil, and only the coil 200 and the copper foil at the bottom of the coil 200 are left. FIG. 7 is a top view of the structure showing the coil 200 on the copper-clad substrate 100.

In step S300, a prepreg 300 and a copper sheet 400 are laminated on the surfaces of the copper-clad substrate 100 to form a first substrate 500.

As shown in FIG. 8, in this example, the prepreg 300 (PP sheet) and the copper sheet 400 are sequentially placed on both the upper surface and the lower surface of the copper-clad substrate 100. The copper sheets 400, the prepregs 300 and the copper-clad substrate 100 form the first substrate 500 by laminating. The coil 200 is covered by the prepregs 300.

In step S400, the first substrate 500 is drilled to define a plurality of first through holes 510 penetrating through the first substrate 500, where the plurality of first through holes 510 are located inside and outside of the coil 200.

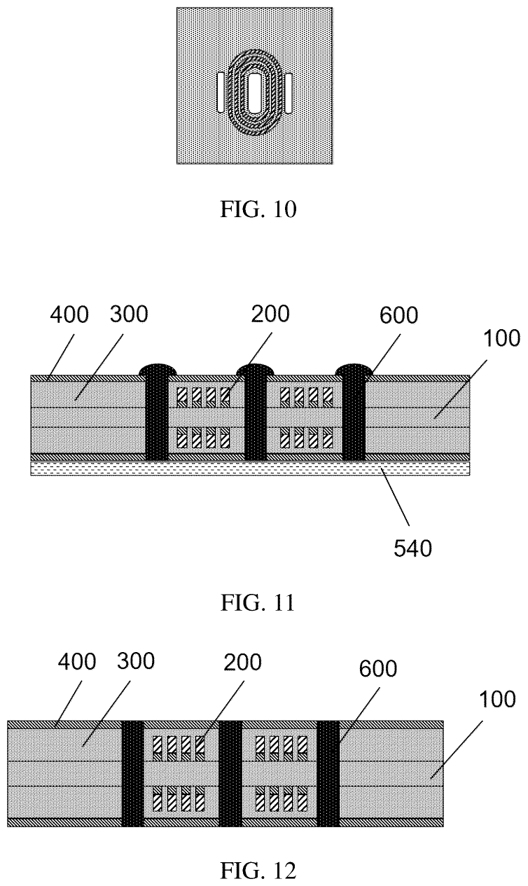

Specifically, as shown in FIG. 9, the drilling can be carried out by mechanical groove milling or laser cutting to define the plurality of first through holes 510 penetrating the first substrate 500. FIG. 10 is a top view of the structure showing the coil 200 and the first through holes 510.

In step S500, a magnetic material is filled in the first through holes 510 to form a first embedded magnet 600.

Specifically, as shown in FIG. 11 to FIG. 13, the above step S500 specifically includes the following three sub-steps of:
1. attaching a bonding adhesive film 540 to a bottom surface of the first substrate 500;
2. filling the magnetic material in the first through holes 510 by screen printing; and
3. removing the bonding adhesive film 540, and grinding the magnetic material to form the first embedded magnet 600 flush with the surfaces of the first substrate 500.

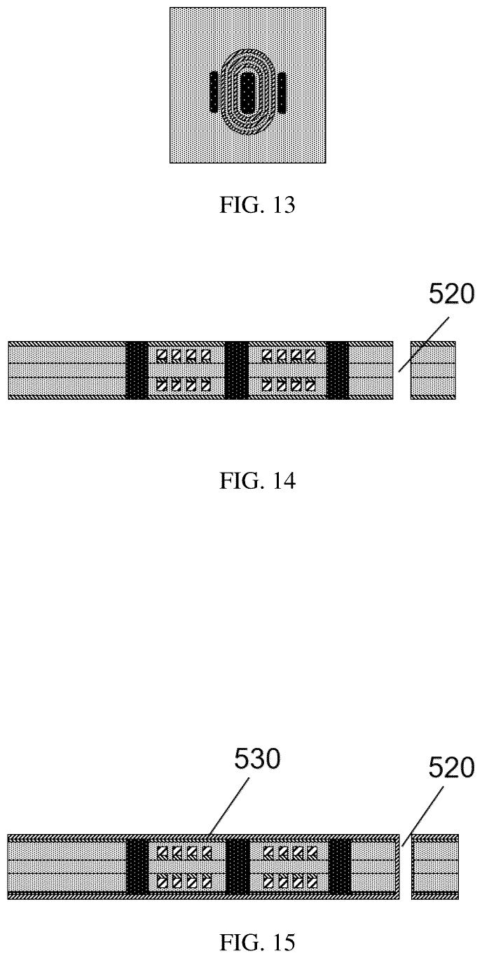

By attaching the temporary bonding adhesive film 540 to the bottom surface of the first substrate 500, the magnetic material can be avoided from flowing out from the bottom of the first through holes 510 when the magnetic material is filled in the first through holes 510; then, the magnetic material is filled in the first through holes 510 by screen printing to reach a magnet structure required by the transformer; and finally, the bonding adhesive film 540 is removed, and a part of excess magnetic material beyond the surface is removed by mechanical grinding, so that the surfaces are flush with the surfaces of the first substrate 500, and the first embedded magnets 600 are formed. FIG. 13 is a top view of the structure showing the first embedded magnets 600 and the coil 200.

In step S600, the first substrate 500 is drilled to define a second through hole 520 penetrating through the first substrate 500, and a metal layer 530 is formed on an inner wall of the second through hole 520 and surfaces of the first substrate 500.

As shown in FIG. 14, the second through hole 520 can be formed by mechanical drilling or laser drilling according to a thickness of the first substrate 500 to serve as an interlayer via hole of the first substrate 500. Then, as shown in FIG. 15, the metal layers 530 is formed on an inner wall of the second through hole 520 and the surfaces of the first substrate 500 by an electroless copper plating technology to satisfy interlayer electrical conductivity.

In step S700, a conductive pillar 700 and a sacrificial block 800 are manufactured on surfaces of the metal layers 530, and the redundant part of the metal layers 530 is etched.

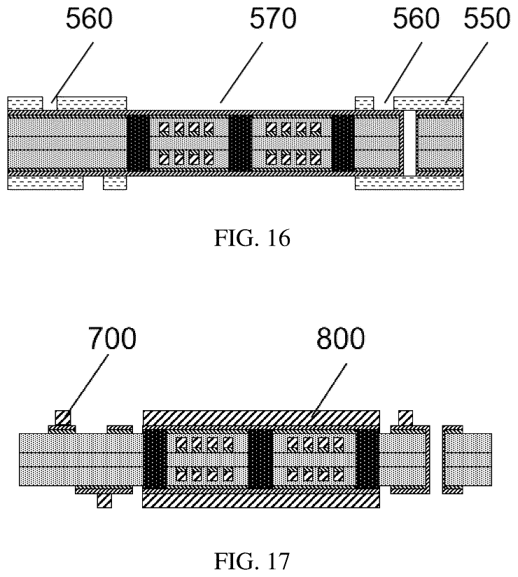

As shown in FIG. 16 and FIG. 17, the above step S700 specifically includes the following four sub-steps of:
1. laminating a photosensitive film 550 on the surfaces of the metal layer 530;
2. windowing the photosensitive film 550 to form a conductive pillar window 560 and a sacrificial block window 570;
3. electroplating in the conductive pillar window 560 to form the conductive pillar 700, and electroplating in the sacrificial block window 570 to form the sacrificial block 800; and
4. removing the photosensitive film 550, and etching the redundant part of the metal layer 530.

As shown in FIG. 16, the photosensitive film 550 is manufactured on the surfaces of the metal layer 530 by laminating, and then the conductive pillar windows 560 and the sacrificial block windows 570 are manufactured as required. As shown in FIG. 17, the electroplating is carried out in the conductive pillar windows 560 to form the conductive pillars 700, the electroplating is carried out in the sacrificial block windows 570 to form the sacrificial blocks 800, then the photosensitive films 550 are removed by film-stripper, and the redundant part of the metal layer 530 is etched.

In step S800, an insulating layer 900 is laminated on the surfaces of the first substrate 500, and the insulating layer 900 covers the conductive pillar 700 and the sacrificial block 800 and is flush with surfaces of the conductive pillar 700 and the sacrificial block 800.

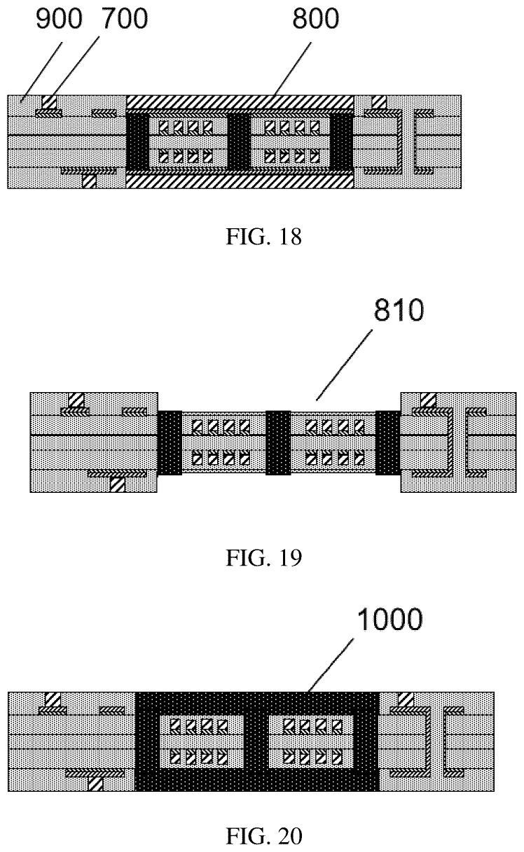

As shown in FIG. 18, the insulating layer 900 is formed on the upper surface and the lower surface of the first substrate 500 by laminating and thinning, and the insulating layers 900 can be of a resin film or PP307 containing glass fiber.

In step S900, the sacrificial blocks 800 are etched to define cavities 810, as shown in FIG. 19.

Specifically, in this example, the above step S900 includes the following four sub-steps of:
1. manufacturing an etching resistant layer (not shown in the drawings) on the surfaces of the first substrate 500 (specifically, the insulating layers 900);
2. windowing the etching resistant layers to expose the sacrificial blocks 800;
3. etching the sacrificial blocks 800 to define the cavities 810; and
4. removing the etching resistant layers.

The etching resistant layers can be made of a photosensitive dry film, and the etching resistant layers are windowed by exposure and development, so as to expose the sacrificial blocks 800, and protect other portions on the surfaces of the insulating layers 900. Then, the sacrificial blocks 800 are etched to define the cavities 810, and the etching resistant layers are removed.

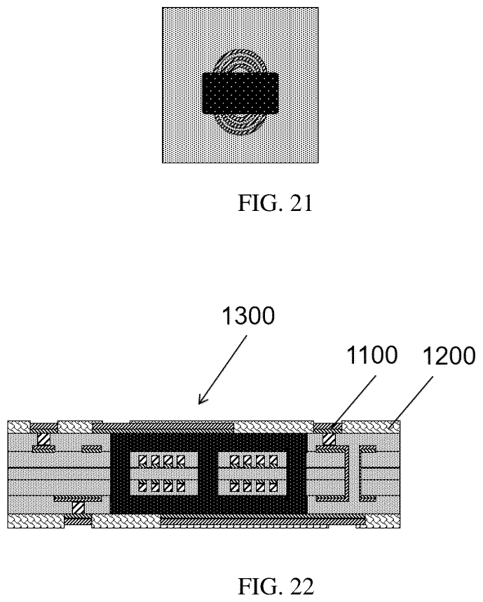

In step S1000, a magnetic material is filled in the cavities 810 to form second embedded magnets 1000; and the first embedded magnets 600 are coupled to the second embedded magnets 1000 to form a closed magnetic circuit, and the magnetic transformer is composed of the closed magnetic circuit and the coil 200. A top view of the magnetic transformer is as shown in FIG. 21.

As shown in FIG. 20, after the magnetic material is filled in the cavities 810, surfaces of the magnetic material are flattened and flush with the surfaces of the insulating layers 900 by mechanical thinning, so as to form the closed magnetic circuit, and the magnetic transformer is formed by the coil 200 formed by a plurality of metal wires in the central of the closed magnetic circuit.

In step S1100, a circuit 1100 and a solder resist layer 1200 are manufactured on surfaces of the insulating layers 900 to form a package substrate 1300, as shown in FIG. 22.

In this example, the above step S1100 specifically includes the following three sub-steps of:
1. manufacturing the circuits 1100 on the surfaces of the insulating layers 900; and connecting the circuits 1100 with the conductive pillars 700 and the second embedded magnets 1000;
2. manufacturing the solder resist layers 1200 on the surfaces of the insulating layers 900, and windowing the solder resist layers 1200 to form windows, so as to expose the circuits 1100; and
3. carrying out a surface treatment on the circuits 1100 according to the window.

The electroplating is carried out on the surfaces of the insulating layers 900 to form the circuits 1100 by photosensitive dry film attachment, exposure, development, electroplating and film stripping, and the circuits 1100 are coupled to the conductive pillars 700 and the second embedded magnets 1000. Then, the solder resist layers 1200 are manufactured on the surfaces of the insulating layers 900, and the solder resist layers 1200 are windowed, so as to expose the circuits 1100, which is convenient for connecting the circuits 1100 with an external electronic element. Finally, the surface treatment is carried out on surfaces of the circuits 1100, so as to protect the circuits 1100.

In the embedding method for the magnetic transformer according to embodiments of the present disclosure, the coil 200 of the transformer is embedded in the package substrate 1300, and the magnetic material is introduced around the coil 200 to form the closed magnetic circuit, which can greatly increase an inductance value of an inductor, effectively reduce an input voltage frequency, reduce a number of turns, reduce direct-current resistance of the coil and an energy loss caused by the transformer, and reduce a size of the transformer at the same time, so that an isolated power supply module or device is miniaturized, the quality requirements of inductor board-level packaging are met, the cost is reduced, and the efficiency is improved.

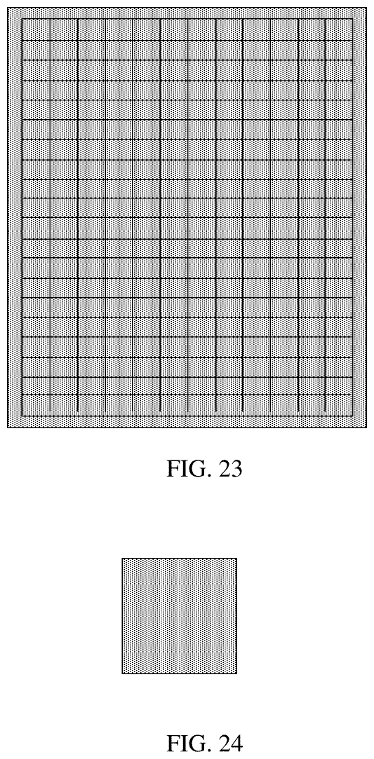

It should be noted that the magnetic embedded transformer product is usually manufactured at a large board level, as shown in FIG. 23, and the embedding method for the magnetic transformer described above is only described for one embedded structure for the magnetic transformer in large-board-level manufacturing.

In another aspect, an embodiment of the present disclosure further provides an embedded structure for a magnetic transformer, wherein the embedded structure of the magnetic transformer is as shown in FIG. 22, and the embedded structure of the magnetic transformer is prepared by the embedding method for the magnetic transformer above.

It should be noted that all the contents in the above method embodiment are applicable to this embodiment, the functions specifically realized by this embodiment are the same as those realized by the above method embodiment, and the beneficial effects achieved by this embodiment are the same as those achieved by the above method embodiment.

In another aspect, an embodiment of the present disclosure further provides an electronic device, which includes:
a memory configured for storing a program instruction; and
a processor configured for calling the program instruction stored in the memory which, when executed by the processor, causes the processor to carry out the embedding method for the magnetic transformer according to the embodiment.

It should be noted that all the contents in the above method embodiment are applicable to this electronic device embodiment, the functions specifically realized by this electronic device embodiment are the same as those realized by the above method embodiment, and the beneficial effects achieved by this electronic device embodiment are the same as those achieved by the above method embodiment.

In another aspect, an embodiment of the present disclosure further provides a storage medium storing a program-executable instruction which, when executed by a computer, causes the computer to carry out the embedding method for the magnetic transformer according to the embodiment.

It should be noted that all the contents in the above method embodiment are applicable to this storage medium embodiment, the functions specifically realized by this storage medium embodiment are the same as those realized by the above method embodiment, and the beneficial effects achieved by this electronic device embodiment are the same as those achieved by the above method embodiment.

Although specific embodiments are described herein, those of ordinary skills in the art will recognize that many other modifications or alternative embodiments are also included in the scope of the present disclosure. For example, any one of functions and/or processing capabilities described in combination with a particular device or component can be executed by any other device or component. In addition, although various exemplary specific implementations and architectures have been described according to the embodiments of the present disclosure, those of ordinary skills in the art will recognize that many other modifications to the exemplary specific implementations and architectures described herein are also included in the scope of the present disclosure.

Some aspects of the present disclosure are described above with reference to the block diagram and the flow chart of the structure, the method, the electric device and/or storage medium according to exemplary embodiments. It shall be understood that one or more blocks in the block diagram and the flow chart, and the combination of the blocks in the block diagram and the flow chart may be implemented by executing the computer-executable program instruction respectively. In the same way, according to some embodiments, some blocks in the block diagram and the flow chart may not need to be executed in the shown sequence, or may not need to be completely executed. In addition, additional components and/or operations beyond those shown in the blocks in the block diagram and the flow chart may exist in some embodiments.

Therefore, the blocks in the block diagram and the flow chart support the combination of apparatuses for executing a specified function, the combination of elements or steps for executing a specified function, and a program instruction apparatus for executing a specified function. It shall also be understood that each block in the block diagram and the flow chart and the combination of the blocks in the block diagram and the flowchart may be implemented by a special-purpose hardware computer system that executes a specific function, element or step or the combination of special-purpose hardware and a computer instruction.

Program modules, applications, and the like described herein may comprise one or more software components, including, for example, a software object, a method, a data structure, and the like. Each such software component may comprise a computer-executable instruction, which is in response to execution to enable at least a portion of the functions described herein (such as one or more operations of the illustrative method described herein) to be executed.

The software component can be encoded in any one of a variety of programming languages. An exemplary programming language can be a low-level programming language, such as an assembly language associated with a particular hardware architecture and/or operating system platform. The software component including an assembly language instruction may need to be converted into an executable machine code by an assembly program before being executed by a hardware architecture and/or platform. Another exemplary programming language can be a higher-level programming language that can be migrated across multiple architectures. The software component including a higher-level programming language may need to be converted into intermediate representation by an interpreter or a compiler before execution. Other examples of the programming languages comprise but are not limited to a macro language, a shell or command language, a job control language, a scripting language, a database query or search language, or a report writing language. In one or more exemplary embodiments, the software component containing the instruction of one of the above programming language examples can be directly executed by an operating system or other software components without first converting to another form.

The software component can be stored as a file or other data storage form. Moreover, the software components with similar types or related functions can be stored together, such as in a specific directory, folder or library. The software component can be static (such as being preset or fixed) or dynamic (such as being created or modified during execution).

The embodiments of the present disclosure are described in detail with reference to the drawings above, but the present disclosure is not limited to the above embodiments, and various changes can also be made within the knowledge scope of those of ordinary skills in the art without departing from the purpose of the present disclosure.

What is claimed is:

1. An embedding method for a magnetic transformer, comprising the following steps of:
providing a copper-clad substrate;
electroplating on an upper surface and a lower surface of the copper-clad substrate to form a coil for the magnetic transformer;
laminating a prepreg and a copper sheet on both the upper surface and the lower surface of the copper-clad substrate to form a first substrate;
drilling the first substrate to define a plurality of first through holes penetrating through the first substrate, wherein at least one of the plurality of first through holes is defined inside the coil, and the rest of the plurality of first through holes is defined outside the coil;
filling a magnetic material in each of the plurality of first through holes to form a respective one of a plurality of first embedded magnets;
drilling the first substrate to define a second through hole penetrating through the first substrate, and forming a plurality of metal layers arranged respectively on an inner wall of the second through hole and an upper surface and a lower surface of the first substrate;
manufacturing a respective one of a plurality of conductive pillars and a respective one of a plurality of sacrificial blocks for each of the plurality of metal layers corresponding to the upper surface and the lower surface of the first substrate, and etching redundant part of the metal layers;
laminating, for the upper surface and the lower surface of the first substrate, an insulating layer, such that the insulating layer is flush with surfaces of the conductive pillars and the sacrificial blocks;
etching each of the plurality of sacrificial blocks to define a respective one of a plurality of cavities corresponding to the upper surface and the lower surface of the first substrate;
filling a magnetic material in each of the plurality of cavities to form a respective one of a plurality of second embedded magnets; wherein the plurality of first embedded magnets are coupled to the plurality of second embedded magnets to form a closed magnetic circuit, and the closed magnetic circuit and the coil form the magnetic transformer; and
manufacturing a circuit and a solder resist layer on a surface of the insulating layers to form a package substrate.

2. The method according to claim 1, wherein the step of electroplating on the upper surface and the lower surface of the copper-clad substrate to form the coil for the magnetic transformer, comprises:
performing the following steps for the upper surface and the lower surface of the copper-clad substrate, comprising:
laminating a photosensitive emulsion film;
exposing and developing the photosensitive emulsion film to define a plurality of coil openings required;
electroplating in each of the plurality of coil opening to form a respective one of a plurality of metal wires; wherein the plurality of metal wires collectively form the coil for the magnetic transformer; and
removing the photosensitive emulsion film, and etching an exposed copper foil.

3. The method according to claim 1, wherein the step of filling the magnetic material in each of the plurality of first through holes to form a respective one of the plurality of first embedded magnets, comprises:
attaching a bonding adhesive film to a bottom of the first substrate;
filling the magnetic material in each of the plurality of first through holes by screen printing; and
removing the bonding adhesive film, and grinding the magnetic material to form the plurality of first embedded magnets each flush with the upper surface and the lower surface of the first substrate.

4. The method according to claim 1, wherein the step of manufacturing a respective one of a plurality of conductive pillars and a respective one of a plurality of sacrificial blocks for each of the plurality of metal layers corresponding to the upper surface and the lower surface of the first substrate, and etching redundant part of the metal layers, comprises:
performing the following steps for the metal layer on the upper surface and the lower surface of the first substrate, comprising:
laminating a photosensitive film on the surface of the metal layer;
windowing the photosensitive film to form a conductive pillar window and a sacrificial block window;
electroplating in the conductive pillar window to form the conductive pillar, and electroplating in the sacrificial block window to form the sacrificial block; and
removing the photosensitive film, and etching the redundant part of the metal layer.

5. The method according to claim 1, wherein the step of etching each of the plurality of sacrificial blocks to define a respective one of a plurality of cavities corresponding to the upper surface and the lower surface of the first substrate, comprises:
performing the following steps for the upper surface and the lower surface of the first substrate, comprising:
manufacturing an etching resistant layer on the surface of the insulating layer;
windowing the etching resistant layer to expose the sacrificial block;
etching the sacrificial block to define the cavity; and
removing the etching resistant layer.

6. The method according to claim 1, wherein the step of manufacturing the circuit and the solder resist layer on the surface of the insulating layers, to form the package substrate, comprises:
performing the following steps for the upper surface and the lower surface of the first substrate, comprising:
manufacturing the circuit on the surface of the insulating layer; wherein the circuit is coupled to the conductive pillar and the second embedded magnet;
manufacturing the solder resist layer on the surface of the insulating layer, and windowing the solder resist layer to form a window, so as to expose the circuit; and
carrying out a surface treatment on the circuit according to the window.

7. The method according to claim 1, wherein the step of forming a plurality of metal layers arranged respectively on an inner wall of the second through hole and an upper surface and a lower surface of the first substrate, comprises:
forming the metal layer on the inner wall of the second through hole and the upper surface and the lower surface of the first substrate by an electroless copper plating technology.

8. An embedded structure for a magnetic transformer, prepared by an embedding method for the magnetic transformer, comprising the following steps of:
providing a copper-clad substrate;
electroplating on an upper surface and a lower surface of the copper-clad substrate to form a coil for the magnetic transformer;
laminating a prepreg and a copper sheet on both the upper surface and the lower surface of the copper-clad substrate to form a first substrate for a package substrate;
drilling the first substrate to define a plurality of first through holes penetrating through the first substrate, wherein at least one of the plurality of first through holes is defined inside the coil, and the rest of the plurality of first through holes is defined outside the coil;
filling a magnetic material in each of the plurality of first through holes to form a respective one of a plurality of first embedded magnets;
drilling the first substrate to define a second through hole penetrating through the first substrate, and forming a plurality of metal layers arranged respectively on an inner wall of the second through hole and an upper surface and a lower surface of the first substrate;
manufacturing a respective one of a plurality of conductive pillars and a respective one of a plurality of sacrificial blocks for each of the plurality of metal layers corresponding to the upper surface and the lower surface of the first substrate, and etching redundant part of the metal layers;
laminating, for the upper surface and the lower surface of the first substrate, an insulating layer, such that the insulating layer is flush with surfaces of the conductive pillars and the sacrificial blocks;
etching each of the plurality of sacrificial blocks to define a respective one of a plurality of cavities corresponding to the upper surface and the lower surface of the first substrate;
filling a magnetic material in each of the plurality of cavities to form a respective one of a plurality of second embedded magnets; wherein the plurality of first embedded magnets are coupled to the plurality of second embedded magnets to form a closed magnetic circuit, and the closed magnetic circuit and the coil form the magnetic transformer; and
manufacturing a circuit and a solder resist layer on a surface of the insulating layers to form the package substrate.

9. The embedded structure according to claim 8, wherein the step of electroplating on the upper surface and the lower surface of the copper-clad substrate to form the coil for the magnetic transformer, comprises:
performing the following steps for the upper surface and the lower surface of the copper-clad substrate, comprising:
laminating a photosensitive emulsion film;
exposing and developing the photosensitive emulsion film to define a plurality of coil openings required;
electroplating in each of the plurality of coil opening to form a respective one of a plurality of metal wires; wherein the plurality of metal wires collectively form the coil for the magnetic transformer; and
removing the photosensitive emulsion film, and etching an exposed copper foil.

10. The embedded structure according to claim 8, wherein the step of filling the magnetic material in each of the plurality of first through holes to form a respective one of the plurality of first embedded magnets, comprises:
attaching a bonding adhesive film to a bottom of the first substrate;
filling the magnetic material in each of the plurality of first through holes by screen printing; and
removing the bonding adhesive film, and grinding the magnetic material to form the plurality of first embedded magnets each flush with the upper surface and the lower surface of the first substrate.

11. The embedded structure according to claim 8, wherein the step of manufacturing a respective one of a plurality of conductive pillars and a respective one of a plurality of sacrificial blocks for each of the plurality of metal layers corresponding to the upper surface and the lower surface of the first substrate, and etching redundant part of the metal layers, comprises:
performing the following steps for the metal layer on the upper surface and the lower surface of the first substrate, comprising:
laminating a photosensitive film on the surface of the metal layer;
windowing the photosensitive film to form a conductive pillar window and a sacrificial block window;
electroplating in the conductive pillar window to form the conductive pillar, and electroplating in the sacrificial block window to form the sacrificial block; and
removing the photosensitive film, and etching the redundant part of the metal layer.

12. The embedded structure according to claim 8, wherein the step of etching each of the plurality of sacrificial blocks to define a respective one of a plurality of cavities corresponding to the upper surface and the lower surface of the first substrate, comprises:
performing the following steps for the upper surface and the lower surface of the first substrate, comprising:
manufacturing an etching resistant layer on the surface of the insulating layer;
windowing the etching resistant layer to expose the sacrificial block;
etching the sacrificial block to define the cavity; and
removing the etching resistant layer.

13. The embedded structure according to claim 8, wherein the step of manufacturing the circuit and the solder resist layer on the surface of the insulating layers, to form the package substrate, comprises:
performing the following steps for the upper surface and the lower surface of the first substrate, comprising:
manufacturing the circuit on the surface of the insulating layer; wherein the circuit is coupled to the conductive pillar and the second embedded magnet;
manufacturing the solder resist layer on the surface of the insulating layer, and windowing the solder resist layer to form a window, so as to expose the circuit; and
carrying out a surface treatment on the circuit according to the window.

14. The embedded structure according to claim 8, wherein the step of forming a plurality of metal layers arranged respectively on an inner wall of the second through hole and an upper surface and a lower surface of the first substrate, comprises:
forming the metal layer on the inner wall of the second through hole and the upper surface and the lower surface of the first substrate by an electroless copper plating technology.

15. An electronic device, comprising:
a memory configured for storing a program instruction; and
a processor configured for calling the program instruction which, when executed by the processor, causes the processor to carry out the embedding method for the magnetic transformer according to claim 1.

16. A non-transitory storage medium, wherein the storage medium stores a computer-executable instruction which, when executed by a computer, causes the computer to carry out the embedding method for the magnetic transformer according to claim 1.
